(19) United States
(12) Patent Application Publication
(10) Pub. No.: US 2025/0391637 A1
(43) Pub. Date: Dec. 25, 2025

(54) SUBSTRATE PROCESSING METHOD

(71) Applicant: TES CO., LTD, Yongin-si (KR)

(72) Inventors: Woo-Young CHUNG, Yongin-si (KR); Hwan-Hee LEE, Yongin-si (KR); Yong-Yi YIN, Yongin-si (KR); Jong-Wook KIM, Yongin-si (KR)

(73) Assignee: TES CO., LTD, Yongin-si (KR)

(21) Appl. No.: 19/243,648

(22) Filed: Jun. 19, 2025

(30) Foreign Application Priority Data
Jun. 24, 2024 (KR) 10-2024-0082012

(51) Int. Cl. H01J 37/32; H01L 21/02

(52) U.S. Cl. CPC H01J 37/32128; H01J 37/32697; H01L 21/02115; H01L 21/02274; H01J 37/321; H01J 2237/332

(57) ABSTRACT

A substrate processing method includes supplying plasma in an interior of a chamber and depositing a hard mask thin film on a top surface of a substrate. The depositing of the hard mask thin film includes applying a voltage in a predetermined waveform to a bias electrode included in an electrostatic chuck. The waveform includes: a first segment having a predetermined positive value; and a second segment converting to a predetermined negative value at an end of the first segment and configured to be a slope having a predetermined gradient. The waveform converts to the predetermined positive value at an end of the second segment, such that the first segment and the second segment are repeated.

### CROSS-REFERENCE TO RELATED APPLICATIONS

A claim for priority under 35 U.S.C. § 119 is made to Korean Patent Application No. 10-2024-0082012 fled on Jun. 24, 2024, in the Korean Intellectual Property Office, the entire contents of which are hereby incorporated by reference.

### BACKGROUND OF THE INVENTION

### Field of the Invention

The present invention relates to a substrate processing method, and more particularly to the substrate processing method capable of reducing particles in a chamber of a substrate processing apparatus that deposits a hard mask thin film on a substrate using inductively coupled plasma in a low temperature process.

### Description of the Related Art

In general, an amorphous carbon layer is applied in various fields such as biomaterials, organic light emitting diodes (OLEDs), semiconductor integrated circuits, solar cells, OLED touch panels, hard masks, and the like.

Particularly, in the semiconductor field where miniaturization and high integration are underway, finer patterns are increasingly required, and the amorphous carbon layer for the hard mask is being used to form such fine patterns.

In order to compensate for the problem of pattern fabrication that may occur due to low selectivity when a conventional amorphous carbon layer is used as a hard mask film, various methods are being developed such as improving the selectivity of thin films by increasing a process temperature, or improving the selectivity by applying new precursors or inductively coupled plasma (ICP) using high plasma density instead of capacitively coupled plasma (CCP).

However, when a high temperature process is used, chamber component durability may be reduced, thermal damage may occur when a subsequent process is further conducted, and additional processes may be required to solve metal contamination problems in the chamber, so the development of the hard mask at a low temperature process is required.

However, if the amorphous carbon layer is formed by the low temperature process, the selectivity thereof is lower than that of a conventional hard mask, so the inductively coupled plasma method that utilizes high energy is suitable, but when the low temperature process is applied, particle issues in the chamber may occur. Therefore, there has been an increasing demand for developing technologies that can reduce particles when the amorphous carbon layer is deposited using the inductively coupled plasma method in the low temperature process.

### SUMMARY OF THE INVENTION

The present invention is contemplated to solve problems in the prior art mentioned above. Thus, it is an object of the present invention to provide a substrate processing method that can maximally suppress particles in a chamber when a hard mask thin film comprising an amorphous carbon layer is deposited on a substrate by a low temperature process.

To solve the above problems, the present invention may provide a substrate processing method for a substrate processing apparatus, which includes a chamber, an upper coil provided to an upper part of the chamber and configured to generate plasma in an interior of the chamber, and an electrostatic chuck provided in the interior of the chamber, the method comprising: supplying the plasma in the interior of the chamber; and depositing a hard mask thin film on a top surface of a substrate, wherein the depositing of the hard mask thin film includes applying a voltage in a predetermined waveform to a bias electrode included in the electrostatic chuck, wherein the waveform includes: a first segment having a predetermined positive value; and a second segment converting to a predetermined negative value at an end of the first segment and configured to be a slope having a predetermined gradient, and wherein the waveform converts to the predetermined positive value at an end of the second segment, such that the first segment and the second segment are repeated.

When the voltage in the waveform is applied to the bias electrode, an ion energy distribution function (IEDF) of ions inside the chamber may have a single-peak form.

The ion energy distribution function (IEDF) of ions inside the chamber may be shifted by adjusting the positive value of the voltage applied in the first segment.

A degree of concentration of the ion energy distribution function (IEDF) of ions inside the chamber may be adjusted by adjusting the gradient of the slope in the second segment.

In the first segment, the substrate may have a predetermined positive voltage value, and in the second segment, the substrate may have a negative voltage value.

The negative voltage value of the substrate may be adjusted by adjusting the gradient of the slope in the second segment.

The substrate may have a constant negative voltage value by adjusting the gradient of the slope in the second segment.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view illustrating an internal configuration of a substrate processing apparatus according to one embodiment of the present invention;

FIG. 2 is a flowchart illustrating a substrate processing method according to the present invention;

FIGS. 3A to 5 are graphs comparing the number of particles adsorbed on a substrate when a process is performed by the substrate processing method of the present invention with the number of particles adsorbed on the substrate when the process is performed by a substrate processing method according to the prior art;

FIGS. 6A and 6B are graphs each illustrating an example where a voltage is applied to a bias electrode by a bias power source according to the prior art;

FIGS. 7A and 7B are graphs each illustrating an example where the voltage is applied to the bias electrode by a bias power source according to the present invention;

FIGS. 8A and 8B are graphs each specifically illustrating a waveform of the voltage supplied by the bias power source according to FIGS. 7A and 7B;

FIGS. 8C and 8D are schematic views illustrating electrons or cations charged on the substrate during the application of the voltage in the waveform according to FIGS. 8A and 8B;

FIGS. 9A and 9B are graphs each illustrating an ion energy distribution function (IEDF) of ions by plasma in a chamber when a voltage waveform according to FIGS. 8A and 8B is applied; and

FIGS. 10A to 10C are graphs illustrating various properties of an amorphous carbon layer when the amorphous carbon layer is deposited by an embodiment according to FIGS. 7A and 7B.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as “comprise”, “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a configuration of a substrate processing apparatus according to an embodiment of the present invention will be described with reference to drawings, and then a substrate processing method will be described.

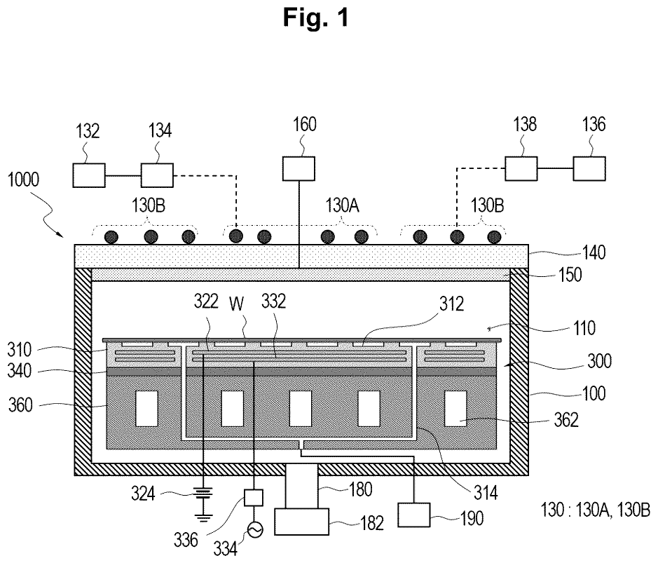

FIG. 1 is a side sectional view illustrating an internal configuration of a substrate processing apparatus 1000 according to one embodiment of the present invention.

Referring to FIG. 1, the substrate processing apparatus 1000 may comprise a chamber 100 providing a processing space 110 for a substrate W, an upper coil 130 provided to an upper part or a top part of the chamber 100 and receiving Radio Frequency (RF) power from RF power sources 132, 136 to generate plasma in the processing space 110, and an electrostatic chuck 300 which is provided inside the chamber 100 and on which the substrate W is seated and fixed.

The substrate processing apparatus 1000 according to the present invention may correspond, for example, to a device for depositing a hard mask thin film on a top surface (or an upper surface) of the substrate W. The hard mask thin film may comprise an amorphous carbon layer and the like. Further, the substrate processing apparatus 1000 may use inductively coupled plasma (ICP) to deposit the hard mask thin film as described above. Moreover, a process for depositing the hard mask thin film which comprises the amorphous carbon film may be a low temperature process in which, for example, an interior of the chamber 100 may have a temperature of about −20° C. to 100° C.

Meanwhile, in the amorphous carbon layer described above, the higher a bond composition of sp3 of carbon increases, the greater a selectivity for etching in a subsequent photolithographic process or the like of the hard mask thin film increases. However, as ion energy by the inductively coupled plasma becomes larger, the bond of carbon shifts from sp3 to sp2, and a proportion of sp3 composition becomes lower.

In the present invention, a high-density plasma may be controlled in the processing space 110 by the upper coil 130, and further, the ion energy may be controlled by inducing ions in the processing space 110 using a bias electrode 332, which is provided to the electrostatic chuck 300. Accordingly, in the substrate processing apparatus 1000, the ions in the processing space 110 may be induced by the bias electrode 332 such that the bond composition of sp3 of carbon in the amorphous carbon layer may be increased by utilizing the ion energy of appropriate intensity. Such a substrate processing apparatus 1000 of the present will be described in detail in the following.

The chamber 100 may provide in an interior or inside thereof, the processing space 110, in which the substrate W is processed and the plasma is generated.

On the upper part of the chamber 100, the upper coil 130 may be provided, which may receive power from the RF power sources 132, 136.

In this case, the upper coil 130 may comprise a plurality of coils 130A, 130B spaced apart along a radial direction from a central portion of the chamber 100. For example, the upper coil 130 may comprise a first coil 130A disposed at a central portion of the chamber 100 and a second coil 130B disposed at a peripheral portion while surrounding the first coil 130A. The number of the coils 130A, 130B may be three or more, and may be suitably varied.

Meanwhile, the RF power sources 132, 136 may comprise a first RF source 132 providing the RF power to the first coil 130A, and a second RF source 136 providing RF power to the second coil 130B. The RF power sources 132, 136 may be configured to generate power with a high frequency (HF) of, for example, 13.56 MHz, and may be configured to provide power of approximately 500 W to 2000 W.

Further, the first RF source 132 may be provided with a first matcher (or matching network) 134 and likewise, the second RF source 136 may be provided with a second matcher (or matching network) 138 to provide tuned power to the first coil 130A and the second coil 130B, respectively. Thereby, the plasma may be generated in the interior of the processing space 110.

Meanwhile, the upper (or top) part of the chamber 100 may be provided with a dielectric window 140 which maintains a pressure inside the chamber 100 and further allows energy generated by the upper coil 130 to pass therethrough. The upper coil 130 may be provided to an upper part or a top part of the window 140.

Further, a lower part (or a bottom part) of the window 140 may be provided with a gas distribution plate 150 for supplying a process gas to the processing space 110. The gas distribution plate 150 may be provided with a plurality of supply holes (not shown) for supplying the process gas. Therefore, the process gas supplied from a process gas source 160 may be supplied to the processing space 110 via the gas distribution plate 150.

Meanwhile, the chamber 100 may be provided with an exhaust channel 180 for exhausting gases, by-products or the like inside the processing space 110, and the exhaust channel 180 may be provided with an exhaust pump 182. The exhaust channel 180 may be provided with a pressure control valve (not shown).

In this case, the exhaust pump 182 may comprise, for example, a turbo molecular pump. By using the turbo molecular pump, a low process pressure inside the chamber 100 may be achieved such that a mean free path of ions is increased to reduce energy losses due to collisions of ions.

Further, the electrostatic chuck 300 on which the substrate W is rested, may be provided in the interior of the chamber 100. The electrostatic chuck 300 may be provided with a chuck electrode 322 that holds the substrate W by electrostatic force and the bias electrode 332 to which a bias power is applied to induce the ions in the processing space 110.

For example, the electrostatic chuck 300 may comprise an upper plate 310 made of a dielectric, a heating plate 340 provided to a lower part of the upper plate 310 to heat the substrate W, and a support plate 360 provided to a lower part of the heating plate 340.

The upper plate 310 may have a flat plate shape comprising the dielectric. The upper plate 310 may comprise at least one of, but not limited to, ceramics such as, for example, Aluminum Oxide (Alumina: Al₂O₃), Aluminum Nitride, Silicon Carbide, Silicon Nitride, and Yttrium Oxide (Yttria: Y₂O₃).

The chuck electrode 322 and the bias electrode 332 may be disposed at or within the upper plate 310. In this case, the chuck electrode 322 may be disposed at an upper part of the upper plate 310, and the bias electrode 332 may be disposed at a lower part of (or below) the chuck electrode 322 at the upper plate 310. Since the electrostatic force exerted by the chuck electrode 322 on the substrate W is inversely proportional to a square of a distance from the substrate W, it is desirable that the chuck electrode 322 be disposed above the bias electrode 332 so as to securely hold the substrate W by the chuck electrode 322.

The chuck electrode 322 may be electrically connected to a direct current power source 324. When a direct current voltage from the direct current power source 324 is applied to the chuck electrode 322, the electrostatic force is generated between the chuck electrode 322 and the substrate W. By such electrostatic force, the substrate W is held on the upper (or top) surface of the upper plate 310.

Meanwhile, the substrate processing apparatus 1000 may further comprise a bias power source 334 that provides the bias electrode 332 with the RF power for inducing the ions in the processing space 110. The bias power source 334 may be configured to generate a low frequency (LF) power of, for example, 360 kHz to 390 kHz, and to provide a power of approximately 500 W to 2000 W. By the low frequency power as described above, the ions of a wide energy range may be induced to deposit the hard mask thin film of the substrate W.

The bias power source 334 may be electrically coupled to the bias electrode 332 of the upper plate 310 via a third matcher (or matching network) 336.

Meanwhile, the lower part of the upper plate 310 may be provided with the heating plate 340 for heating the substrate W. The heating plate 340 may be configured to have, for example, an embedded (or built-in) film heater (not shown). However, the film heater is described by way of example and the heating plate 340 may be configured in various mechanism. bonding layers (not shown) may be provided to the upper and lower parts of the heating plate 340.

Further, the lower part of the heating plate 340 may be provided with the support plate 360. The support plate 360 may be made of metal, for example, Aluminum or the like. Although the support plate 360 is shown as a single member in FIG. 1, the support plate 360 is not limited thereto and may include two or more members.

The support plate 360 may be provided with a heat transfer channel 362 through which heat transfer fluid flows. A temperature of the support plate 360 may be regulated by the heat transfer fluid flowing through the heat transfer channel 362.

Meanwhile, the upper plate 310 may be formed with a plurality of grooves 312, and the plurality of grooves 312 may be distributed on the upper (or top) surface of the upper plate 310.

In this case, a gas channel 314 may be formed at the electrostatic chuck 300 to penetrate through the electrostatic chuck 300 and to be connected to the grooves 312. That is, the gas channel 314 may pass through the support plate 360, the heating plate 340, and the upper plate 310 from a bottom of the electrostatic chuck 314 and then may be connected to the grooves 312.

A cooling gas, such as Helium (He) or the like, may be supplied from a cooling gas source 190 via the gas channel 314, and then may be supplied toward the bottom surface of the substrate W via the groove 312, so as to cool the substrate W.

In particular, when the substrate W is fixed and retained on the upper or top surface of the upper plate 310 by the chuck electrode 322, the cooling efficiency by the cooling gas supplied through the groove 312 may be increased. In addition, it may be possible for the bias electrode 332 as described above to prevent the temperature rise of the substrate W caused by the ions in the processing space 110 which move toward and impinge on the substrate W.

Meanwhile, when the amorphous carbon layer is formed using an inductively coupled plasma by a low temperature process as disclosed in the present invention, a problem of particles in the chamber may occur. In the following, a substrate processing method capable of reducing the particles in the chamber 100 of the substrate processing apparatus 1000 having the configuration as described above, will be described.

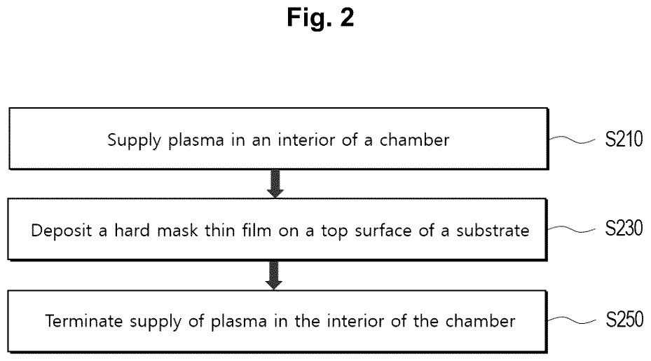

FIG. 2 is a flowchart illustrating the substrate processing method according to the present invention.

Referring to FIG. 1 and FIG. 2, the substrate processing method may comprise a step S210 of supplying the plasma into the interior of the chamber 100, a step S230 of depositing the hard mask thin film on the upper (or top) surface of the substrate W, and a step S250 of stopping or terminating the supply of plasma in the interior of the chamber 100.

First, the substrate W is introduced into the interior of the chamber 100, and is seated on the upper part of the electrostatic chuck 300.

Then, Argon (Ar) gas may be supplied via the gas distribution plate 150 to provide the plasma to the processing space 110, and the RF power may be applied to the upper coil 130.

In this case, if the RF power is applied to the upper coil 130 at a target value, for example, 1000 W, immediately or directly from the beginning, damage to an inner wall of the chamber 100 by the plasma may occur, resulting in a large number of particles.

Therefore, in order to solve this problem, the present invention gradually or progressively increases the RF power after supplying the RF power to the upper coil 130 (specifically, after initiating supplying of the RF power to the upper coil 130), in the step of supplying the plasma to the interior of the chamber 100.

Further, in gradually increasing the RF power applied to the upper coil 130, the RF power may be increased in steps, stages, or phases (i.e., step by step). For example, a power of 100 W to 300 W may be initially applied to the upper coil 130, and a power of 400 W to 1000 W may be applied after a predetermined time period. The number of steps of increasing the RF power in this manner may be suitably varied.

By gradually increasing the RF power applied to the upper coil 130 as disclosed in the present invention, the plasma may be gradually changed from a state with a low density of the plasma to a state with a high density of the plasma, thereby minimizing the damage to the inner wall of the chamber 100 and suppressing particle generation.

Meanwhile, in increasing the RF power step by step, it is preferable to keep the difference of the RF power in each step to be constant. For example, a power of 100 W to 300 W may be initially applied to the upper coil 130, then, a power of 400 W to 600 W may be applied, and finally a power of 700 W to 900 W may be applied. In this case, the intensity of the plasma inside the processing space 110 may be equally increased, such that the particles that may occur on the inner wall of the chamber 100 may be reduced so that

Subsequently, a voltage may be applied to the chuck electrode 322 of the electrostatic chuck 300 to hold the substrate W, and the hard mask thin film may be deposited on the upper surface of the substrate W by supplying the process gas through the gas distribution plate 150.

In this case, the RF power may be applied to the upper coil 130, and also the RF power may be applied to the bias electrode 332.

After the hard mask thin film is deposited on the upper surface of the substrate W, the plasma supply is stopped inside the chamber 100.

In this case, if the RF power applied to the upper coil 130 is turned off at once, the particles and the like that are captured by the plasma electric field and located above the substrate W may fall or drop to the upper surface of the substrate W simultaneously with the turning off of the RF power.

Therefore, in the present invention, the RF power supplied to the upper coil 130 is gradually or progressively reduced (or decreased) to turn off the RF power, in the step of stopping the plasma supply inside the chamber 100.

In this case, in gradually reducing the RF power, the RF power may be reduced in steps, stages, or phases.

For example, the RF power applied to the upper coil 130 may be gradually reduced over a plurality of steps.

Further, while the RF power is gradually reduced, an amount of inert gas such as Argon gas supplied through the gas distribution plate 150 may be increased. For example, approximately 2 to 3 times of the amount of inert gas may be supplied compared to an amount of inert gas supplied during the process for the substrate W.

As such, increasing the supply of argon gas may allow the exhaust pump 182 to more effectively evacuate contaminants such as the particles and the like inside the chamber 100, thereby reducing the attachment of particles and the like to the substrate W.

The RF power applied to the bias electrode 332 may be gradually reduced or turned off immediately.

Meanwhile, when the hard mask thin film is deposited on the upper surface of the substrate W and the RF power supplied to the upper coil 130 is interrupted or terminated, the RF power supply to the first coil 130A disposed in the central portion of the chamber 100 may be interrupted first, and the RF power supply to the second coil 130B may be interrupted after a predetermined time period.

In this case, when the RF power supply to the first coil 130A is interrupted first, the plasma disappears in a lower part of (or below) the first coil 130A, and the plasma remains in a lower part of (or below) the second coil 130B located on the periphery. Further, the particles and the like move together to the outskirts, periphery or edges of the processing space 110, as a region of plasma moves to the periphery of the processing space 110.

In such a state, increasing the amount of inert gas such as Argon gas supplied through the gas distribution plate 150 enables more effective evacuation of contaminants such as the particles inside the chamber 100, thereby reducing the adhesion of particles and the like to the substrate W.

The RF power supply to the first coil 130A may be interrupted, and then, the RF power supply to the second coil 130B may be interrupted after a predetermined time period.

Subsequently, the application of voltage to the chuck electrode 322 of the electrostatic chuck 300 is stopped or terminated, the substrate W is dechucked, and such a substrate W is transferred to an outside of the chamber 100.

In this case, an opening (not shown) of the chamber 100 may be opened to cause a sudden change in the pressure inside the chamber 100, and this may induce scattering of particles or the like inside the chamber 100.

Therefore, in order to prevent such scattering of particles, the amount of supply of an inert gas such as Argon gas supplied through the gas distribution plate 150, may be adjusted to maintain a constant pressure inside the chamber 100 when the substrate W is moved out.

That is, by minimizing the pressure change inside the chamber 100 by a flow rate of Argon gas, particle scattering that may be caused by a sudden pressure change inside the chamber 100, may be suppressed.

Meanwhile, the hard mask thin film made of the amorphous carbon layer may be deposited on the substrate W by the steps described above, and then a step of cleaning the inside of the chamber 100 may be performed. Such a cleaning step may be performed after performing a process of depositing the hard mask thin film on the substrate W once, or may be performed after repeating a deposition process a plurality of times. For example, the deposition process may be performed four times and the cleaning process may be performed one time, and the number of such times may be adjusted appropriately.

The cleaning of the amorphous carbon thin layer inside the chamber 100 is carried out by an ashing process which uses an oxygen (O₂) plasma. In this manner, the particles detached from the inner wall of the chamber 100 and moisture (H₂O) absorbed by the inner wall of the chamber 100 may be removed by the reaction of hydrogen and oxygen in the amorphous carbon layer.

In this case, while oxygen is supplied into the interior of the chamber 100, a step of applying the RF power to the upper coil 130 and the bias electrode 332, and a step of applying the RF power to the upper coil 130 only, may be repeated several times.

That is, the RF power may be applied to both the upper coil 130 and the bias electrode 332 to clean the interior of the chamber 100 including a lower region thereof, and then RF power may be applied to only the upper coil 130 to clean an upper region of the interior of the chamber 100. Such steps may be repeated to effectively clean the interior of the chamber 100.

Meanwhile, in the step of cleaning the interior of the chamber 100, a step of providing the plasma by supplying hydrogen to the interior of the chamber 100 may be performed.

That is, at an end of the step of cleaning the interior of the chamber 100, a hydrogen plasma may be provided by applying the RF power to the upper coil 130 or to both of the upper coil 130 and the bias electrode 332 while a hydrogen gas is supplied into the interior of the chamber 100. By performing a post processing by the hydrogen plasma as such, the particles may be reduced by removing residual impurities or the like that are attached to the inner wall of the chamber 100.

Meanwhile, after the step of cleaning the interior of the chamber 100, a step of purging the interior of the chamber 100 may be performed.

In this case, in order to effectively exhaust the residual gas, residue, etc. in the interior of the chamber 100, the supply and interruption of a purge gas such as helium (He) gas to the interior of the chamber 100 may be repeated. Thereby, the pressure inside the chamber 100 changes and fluctuates rapidly, so that a so-called “cyclic purge” may be performed. Meanwhile, the exhaust pump 182 may be continuously operated in such a step as described above.

Meanwhile, the substrate processing apparatus 1000 may further comprise a remote plasma source (RPS) (not shown) that provides remote plasma into the chamber 100, and may provide the remote plasma into the interior of the chamber 100 using the RPS.

That is, the process of depositing the hard mask thin film on the substrate W described above may be repeated a plurality of times, the process of cleaning the chamber 100 may also be repeated a plurality of times, and then a step of providing the remote plasma may be performed. For example, the process of depositing the hard mask thin film on the substrate W may be repeated about 40 times, the process of cleaning the chamber 100 may be repeated about 10 times, and then the step of providing the remote plasma may be performed.

Meanwhile, the remote plasma source (RPS) may be connected to a side of the chamber 100, or to the lower part thereof, to supply the remote plasma into the interior of the chamber 100, thereby efficiently cleaning the lower region of the interior of the chamber 100.

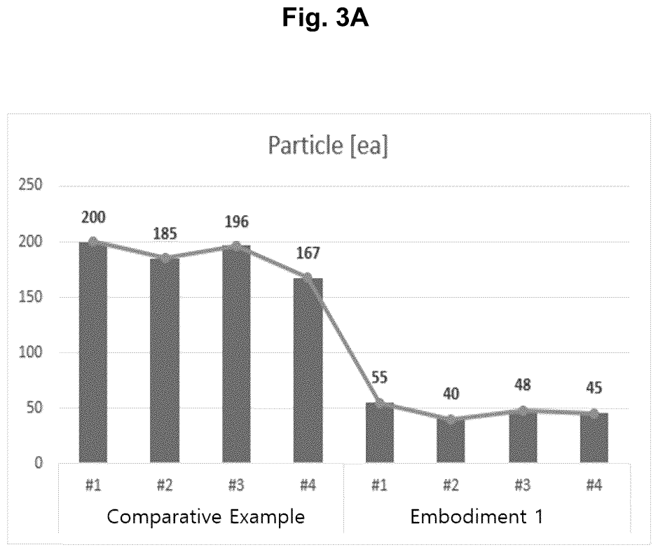

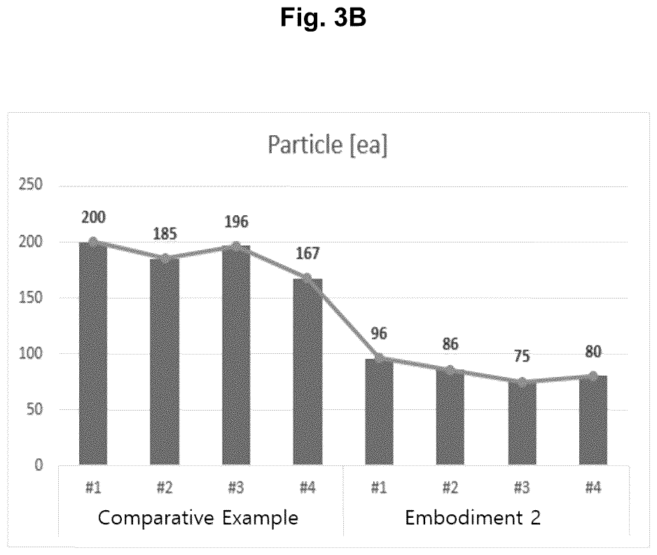

Meanwhile, FIG. 3A to FIG. 5 are graphs comparing the number of particles adsorbed on the substrate when the process is performed by the substrate processing method of the present invention described above, with the number of particles adsorbed on the substrate when the process is performed by a substrate processing method according to the prior art.

First, FIG. 3A is a graph comparing the number of particles adsorbed on the substrate when the process is conducted by gradually increasing the RF power after supplying the RF power to the upper coil 130 in the step of supplying the plasma inside the chamber 100 (Embodiment 1), with the number of particles adsorbed on the substrate when the substrate processing method according to the prior art that does not include such a step of gradually increasing the RF power is applied (Comparative Example).

Referring to FIG. 3A, it can be observed that when the process is performed according to Embodiment 1, the particles are reduced by approximately 20% to 33% compared to Comparative Example.

Further, FIG. 3B is a graph comparing the number of particles adsorbed on the substrate when the process is conducted by gradually reducing the RF power supplied to the upper coil 130 to turn off the RF power in the step of stopping the plasma supply inside the chamber 100 (Embodiment 2), with the number of particles adsorbed on the substrate when the substrate processing method according to the prior art that does not include such a step of gradually reducing the RF power is applied (Comparative Example).

Referring to FIG. 3B, it can be observed that when the process is performed according to Embodiment 2, the particles are reduced by approximately 38% to 55% compared to Comparative Example.

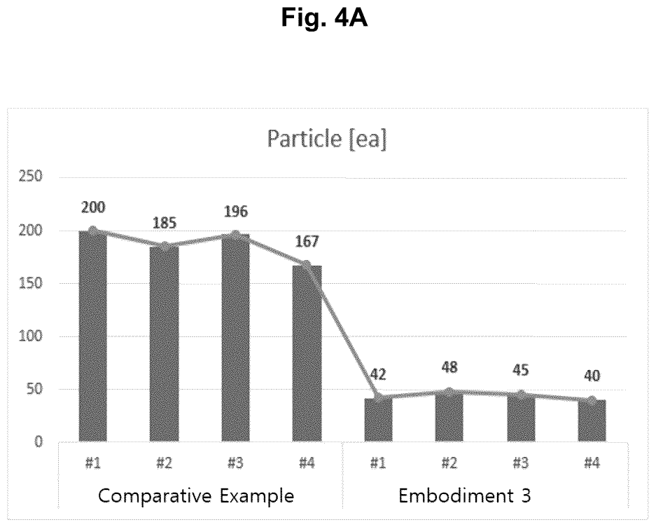

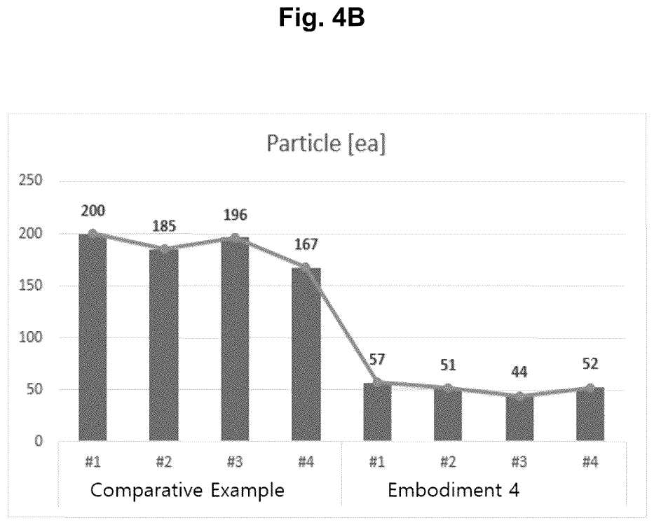

Meanwhile, FIG. 4A is a graph comparing the number of particles adsorbed on the substrate when the process including the step of reducing the pressure change inside the chamber 100 by Argon gas is conducted when the substrate W is transferred from the inside of the chamber 100 to the outside (Embodiment 3), with the number of particles adsorbed on the substrate when the substrate processing method according to the prior art that does not include such a step of reducing the pressure change is applied (Comparative Example).

Referring to FIG. 4A, it can be observed that when the process is performed according to Embodiment 3, the particles are reduced by approximately 20% to 28% compared to Comparative Example.

Further, FIG. 4B is a graph comparing the number of particles adsorbed on the substrate when the process including the hydrogen plasma processing step as described above is conducted (Embodiment 4), with the number of particles adsorbed on the substrate when the substrate processing method according to the prior art that does not include such a hydrogen plasma processing step is applied (Comparative Example).

Referring to FIG. 4B, it can be observed that when the process is performed according to Embodiment 4, the particles are reduced by approximately 22% to 34% compared to Comparative Example.

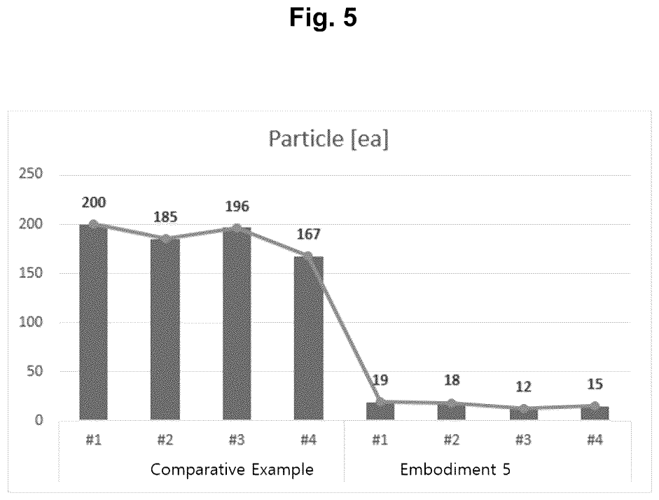

Meanwhile, FIG. 5 is a graph comparing the number of particles adsorbed on a substrate when a process including all of the steps of FIGS. 3A, 3B, 4A and 4B described above is conducted (Embodiment 5), with the number of particles adsorbed on the substrate when the substrate processing method according to the prior art that does not include all of the steps of FIGS. FIGS. 3A, 3B, 4A and 4B described above is applied (Comparative Example).

Referring to FIG. 5, it can be observed that the particles are significantly reduced by approximately 6% to 11% compared to Comparative Example when the process is performed according to Embodiment 5.

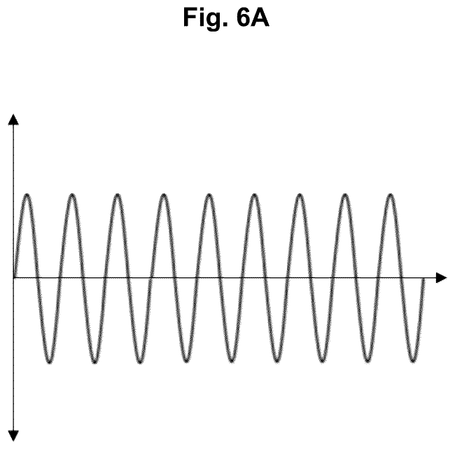

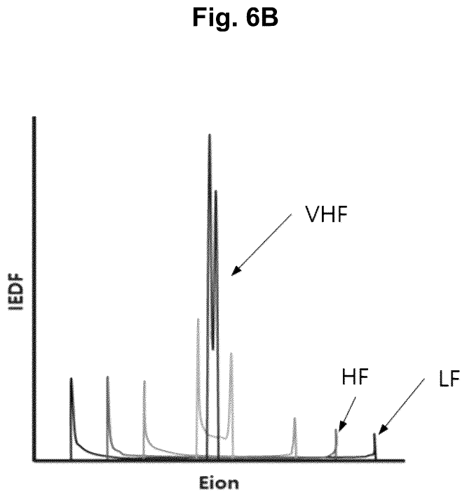

Meanwhile, FIGS. 6A and 6B are drawings for describing a substrate processing method according to another embodiment. Specifically, FIGS. 6A and 6B may correspond to a method of adjusting the voltage applied to the bias electrode 332 in the step S230 of depositing the hard mask thin film on the upper surface of the substrate W, or in an etching process such as a subsequent photolithographic process of the hard mask thin film and the like.

FIGS. 6A and 6B are graphs each illustrating the application of the voltage to the bias electrode 332 by the bias power source 334 according to the prior art.

As shown in FIG. 6A, in the prior art, a voltage of a so-called “sine wave” waveform may be applied to the bias electrode 332 by the bias power source 334.

In this case, an ion energy distribution function (IEDF) of the ions by the plasma inside the chamber 100, as shown in FIG. 6B, appears to be in a form having two peaks, such as a bimodal form, or a twin peak form.

When the ion energy distribution function (IEDF) of the ions exhibits the bimodal or twin peak shape, the ion energy is distributed over a wide range. In this case, the ion energy contributing to the film deposition is concentrated in a specific band, and thus, only a portion of the ion energy contributes to the film growth, while the remaining energy may increase the temperature of the substrate and increase the stress in the film. In addition, such an IEDF increases the bond composition of sp2 of the carbon in the amorphous carbon layer, which reduces the quality of the thin film.

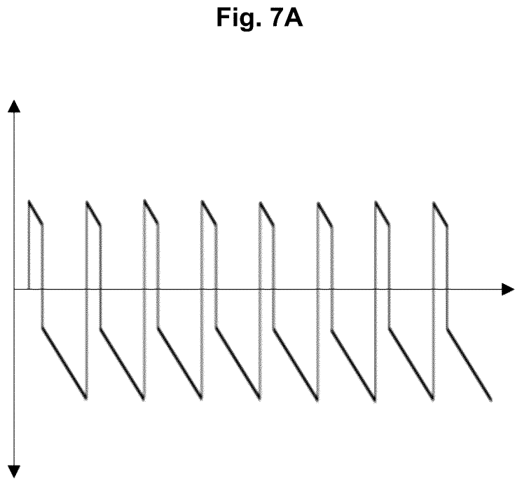

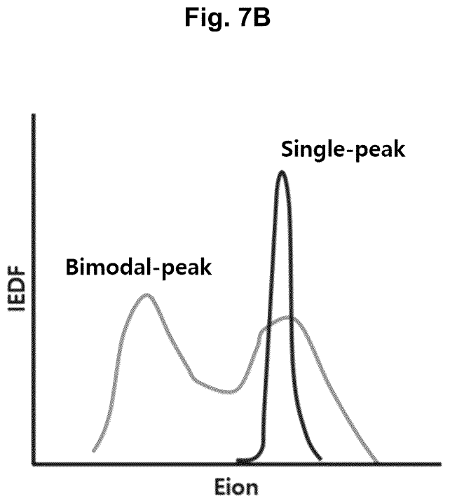

FIGS. 7A and 7B are graphs each illustrating the application of the voltage to the bias electrode 332 by the bias power source 334, according to the present embodiment.

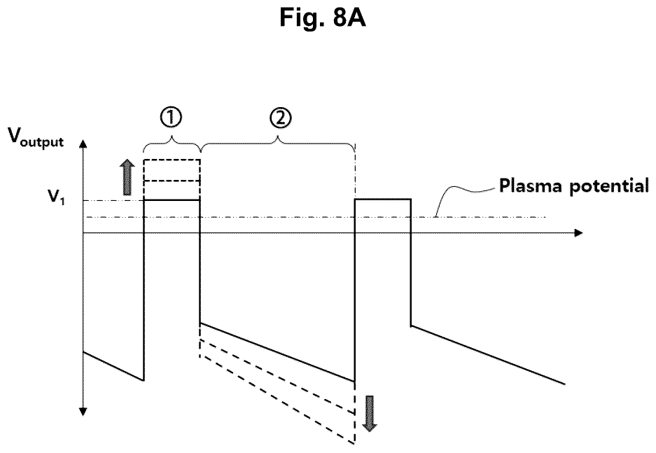

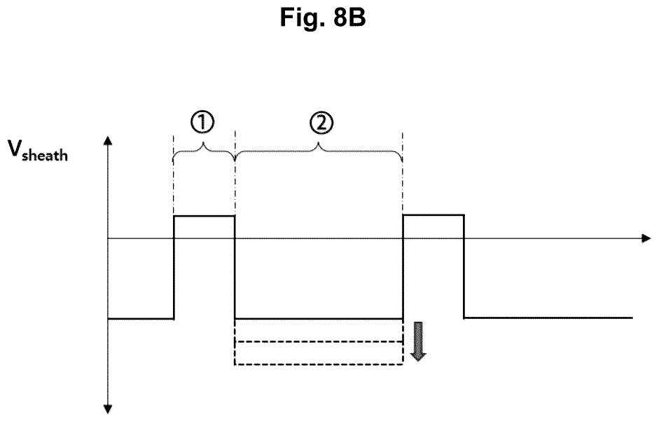

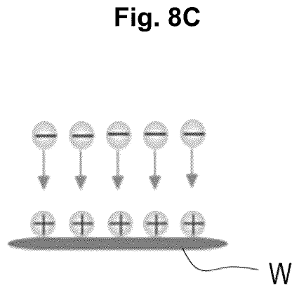

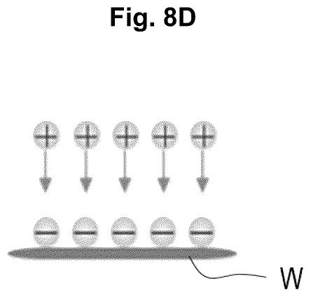

As shown in FIG. 7A, the bias power source 334 may apply a voltage in a predetermined waveform. The waveform will be discussed in more detail with respect to FIG. 8.

When the waveform corresponding to FIG. 7A is applied to the bias electrode 332, it can be noted that the ion energy distribution function (IEDF) of the ions by the plasma inside the chamber 100 changes from the bimodal or the twin peak form to a single-peak form. In FIG. 7B, a single-peak distribution according to the present embodiment is shown along with a bimodal distribution according to the prior art.

When the ion energy distribution function (IEDF) of the ions appears in the single-peak form, the ion energy may be concentrated in a narrow range. In this case, most of the ion energy is contributed to the deposition of the thin film, and the temperature rise of the substrate may be maximally suppressed. Further, the increase of stress in the thin film may be minimized, and the quality of the thin film may be improved by increasing the bond composition of sp3 of carbon in the amorphous carbon layer.

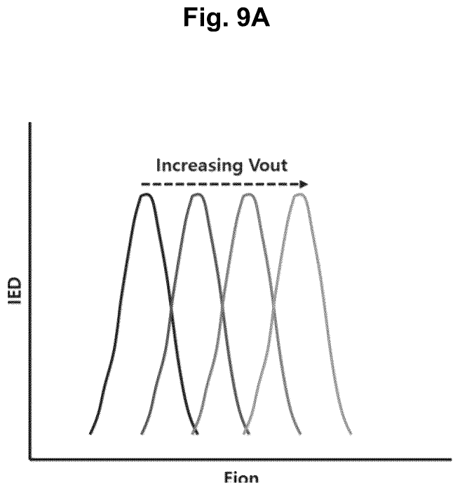

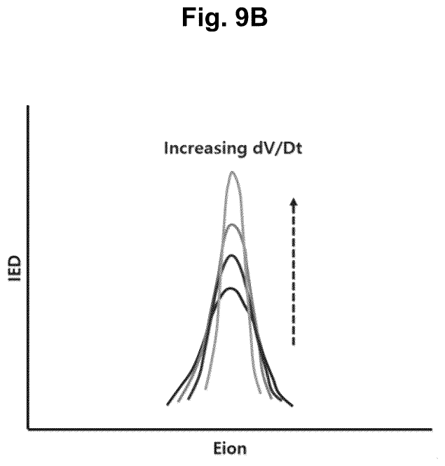

FIGS. 8A and 8B are graphs specifically illustrating the waveform of the voltage supplied by the bias power source 334 according to FIGS. 7A and 7B. FIG. 8A is a graph illustrating the waveform of the voltage (Vₒᵤₜₚᵤₜ), and FIG. 8B corresponds to a graph measuring a voltage of the substrate W (Vₛₕₑₐₜₕ). FIGS. 8C and 8D are schematic views illustrating electrons or cations charged on the substrate during the application of the voltage in the waveform according to FIGS. 8A and 8B. Meanwhile, FIGS. 9A and 9B each show the ion energy distribution function (IEDF) of the ions by the plasma inside the chamber 100 when the voltage waveform according to FIGS. 8A and 8B is applied.

As shown in FIG. 8A, the waveform may comprise a first segment \textcircled{1} having a predetermined positive value (V₁), and a second segment \textcircled{2} switching or converting to a predetermined negative value at an end of the first segment \textcircled{1} and configured as a slope having a predetermined gradient or inclination. The first or second segment may be referred to a first or second section, block, interval, step, stage, phase, region or the like. At an end of the second segment \textcircled{2}, the waveform transitions or converts to the predetermined positive value, and thereby, the first segment \textcircled{1} and the second segment \textcircled{2} may be repeated.

Further, as shown in FIG. 8A, the voltage of the substrate W may change according to the change of the waveform.

For example, as shown in FIG. 8B, in the first segment \textcircled{1}, the voltage of the substrate W may have a constant positive value. Further, in the second segment \textcircled{2}, the voltage of the substrate W may have a negative value. Further, when the gradient of the slope is adjusted in the second segment \textcircled{2}, the voltage of the substrate W may maintain an approximately constant negative value.

Meanwhile, in the first segment \textcircled{1}, electrons are attracted to and charged on the substrate W as shown in FIG. 8C. Then, in the second segment \textcircled{2}, positive ions are attracted and charged as shown in FIG. 8D.

Meanwhile, the ion energy distribution function (IEDF) of the ions shown in FIG. 9A may be shifted by adjusting the predetermined positive value (V₁) in the first segment \textcircled{1}. For example, by increasing the predetermined positive value (V₁) in the first segment \textcircled{1} along the arrow, the ion energy distribution function (IEDF) of the ions as shown in FIG. 9A may be shifted to the right to represent the higher energy.

Meanwhile, when the gradient of the slope is changed in the second segment \textcircled{2}, a negative value of the voltage at the substrate W may be changed, as shown in FIG. 8B.

Further, when a value of the gradient (dV/dt) of the slope is increased in the direction of the arrow as shown in FIG. 8A in the second segment \textcircled{2}, the amount or degree of energy concentration may be adjusted by making a top portion of the ion energy distribution function (IEDF) of the ions have a more pointed (sharp) shape, as shown in FIG. 9B.

Moreover, by increasing or decreasing the gradient of the slope, or by changing the gradient of the slope to have the positive value, in this case, the negative value of the voltage of the substrate W may be changed, and further, the voltage of the substrate W may be changed to a value having a uniform gradient rather than the constant negative value.

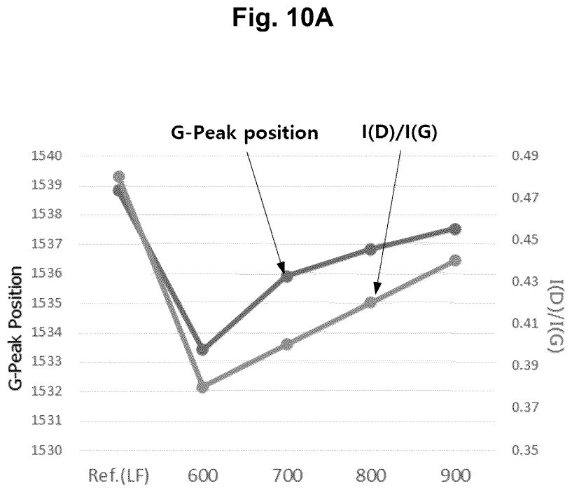

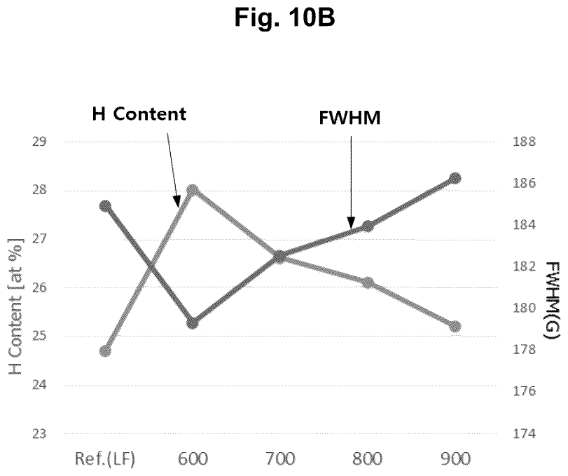

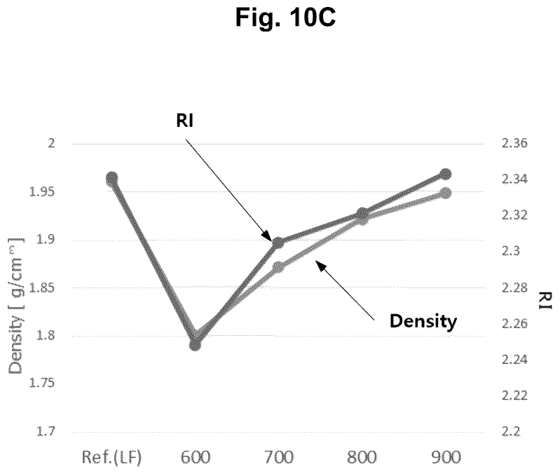

Meanwhile, FIGS. 10A to 10C are graphs illustrating various properties of the amorphous carbon layer when the amorphous carbon layer is deposited by the embodiment according to FIGS. 7A and 7B.

FIG. 10A shows a G-peak position and an I(D)/I(G) value of the amorphous carbon layer, FIG. 10B shows an H content (at %) and a FWHM (G) of the amorphous carbon layer, and FIG. 10C shows a density (g/cm³) and an RI value of the amorphous carbon layer. In each of the graphs of FIGS. 10A to 10C, the horizontal axis shows the voltage value supplied by the bias power source 334.

As shown in FIGS. 10A to 10C, it can be observed that when the voltage increases, the density (g/cm³) and the RI value of the amorphous carbon layer increase. Further, it can be observed that when the voltage increases, the G-peak position and I(D)/I(G) value of the amorphous carbon layer increase. Moreover, it can be observed that when the voltage increases, the FWHM (G) of the amorphous carbon layer increases, while the H content (at %) decreases.

The substrate processing method according to the present invention has the technical advantages as follows.

According to the present invention having the configuration described above, the particles in the chamber can be suppressed as much as possible when the hard mask thin film comprising the amorphous carbon layer is deposited on the substrate using the low temperature process.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing method for a substrate processing apparatus, which includes a chamber, an upper coil provided to an upper part of the chamber and configured to generate plasma in an interior of the chamber, and an electrostatic chuck provided in the interior of the chamber, the method comprising:
supplying the plasma in the interior of the chamber; and
depositing a hard mask thin film on a top surface of a substrate,
wherein the depositing of the hard mask thin film includes applying a voltage in a predetermined waveform to a bias electrode included in the electrostatic chuck,
wherein the waveform includes:
a first segment having a predetermined positive value; and
a second segment converting to a predetermined negative value at an end of the first segment and configured to be a slope having a predetermined gradient, and
wherein the waveform converts to the predetermined positive value at an end of the second segment, such that the first segment and the second segment are repeated.

2. The substrate processing method of claim 1, wherein when the voltage in the waveform is applied to the bias electrode, an ion energy distribution function (IEDF) of ions inside the chamber has a single-peak form.

3. The substrate processing method of claim 1, wherein an ion energy distribution function (IEDF) of ions inside the chamber is shifted by adjusting the positive value of the voltage applied in the first segment.

4. The substrate processing method of claim 1, wherein a degree of concentration of an ion energy distribution function (IEDF) of ions inside the chamber is adjusted by adjusting the gradient of the slope in the second segment.

5. The substrate processing method of claim 1, wherein in the first segment, the substrate has a predetermined positive voltage value, and in the second segment, the substrate has a negative voltage value.

6. The substrate processing method of claim 1, wherein a negative voltage value of the substrate is adjusted by adjusting the gradient of the slope in the second segment.

7. The substrate processing method of claim 1, wherein the substrate has a constant negative voltage value by adjusting the gradient of the slope in the second segment.
